(19) United States
(12) Patent Application Publication
(10) Pub. No.: US 2026/0094662 A1
(43) Pub. Date: Apr. 2, 2026

(54) RECONFIGURATION DATA HANDLING

(71) Applicant: Cypres Semiconductor Corporation, San Jose, CA (US)

(72) Inventor: Senwen Kan, Austin, TX (US)

(73) Assignee: Cypress Semiconductor Corporation, San Jose, CA (US)

(21) Appl. No.: 18/900,022

(22) Filed: Sep. 27, 2024

(51) Int. Cl. G11C 29/44; G06F 11/10

(52) U.S. Cl. CPC G11C 29/4401; G06F 11/106; G11C 2029/4402

(57) ABSTRACT

In an embodiment of the techniques presented herein, a positional codec system includes a protocol engine configured to receive a stream of test data associated with a device, a detection circuit configured to identify first care data at a first position in the stream of test data corresponding to a first element of the device, and a first access module configured to send a first write command to store the first care data and the first position to a reconfiguration memory.

### BACKGROUND

Integrated circuits (ICs) are experiencing continuous improvements in the integration density of various components (e.g., transistors, diodes, resistors, capacitors, etc.). Reconfiguration data is employed in a device to address defective components, such as memory cells.

### SUMMARY

This Summary is provided to introduce a selection of concepts in a simplified form that are further described below in the Detailed Description.

This Summary is not intended to identify key factors or essential features of the claimed subject matter, nor is it intended to be used to limit the scope of the claimed subject matter.

In an embodiment of the techniques presented herein, a method comprises receiving a stream of test data associated with a device, identifying first care data at a first position in the stream of test data corresponding to a first element of the device, and sending a first write command comprising the first care data and the first position to a reconfiguration memory.

In an embodiment of the techniques presented herein, a positional codec system comprises a protocol engine configured to receive a stream of test data associated with a device, a detection circuit configured to identify first care data at a first position in the stream of test data corresponding to a first element of the device, and a first access module configured to send a first write command to store the first care data and the first position to a reconfiguration memory.

In an embodiment of the techniques presented herein, a device comprises a reconfiguration memory, a module comprising elements and a reconfiguration register, a repair controller configured to receive a stream of test data associated with the module, and a positional codec system comprising a protocol engine configured to receive the stream of test data from the repair controller, a detection circuit configured to identify first care data at a first position in the stream of test data corresponding to a first element of the elements in the module, and a first access module configured to store the first care data and the first position in the reconfiguration memory, wherein the repair controller is configured to program the reconfiguration register using the first care data to set a parameter associated with the first element or designate a second element as a replacement for the first element.

In an embodiment of the techniques presented herein, a system comprises means for receiving a stream of test data associated with a device, means for identifying first care data at a first position in the stream of test data corresponding to a first element of the device, and means for sending a first write command comprising the first care data and the first position to a reconfiguration memory.

To the accomplishment of the foregoing and related ends, the following description and annexed drawings set forth certain illustrative aspects and implementations. These are indicative of but a few of the various ways in which one or more aspects may be employed. Other aspects, advantages, and novel features of the disclosure will become apparent from the following detailed description when considered in conjunction with the annexed drawings.

### DESCRIPTION OF THE DRAWINGS

FIG. 1 is a diagram of a device employing reconfiguration data, in accordance with some embodiments.

FIG. 2 is diagram of a positional codec system, in accordance with some embodiments.

FIG. 3 is diagram illustrating reconfiguration data processing with a cache, in accordance with some embodiments.

FIG. 4 is diagram illustrating reconfiguration data processing without a cache, in accordance with some embodiments.

FIG. 5 is a diagram of a method for writing reconfiguration data in a device, in accordance with some embodiments.

FIG. 6 is a diagram of a method for reading reconfiguration data in a device, in accordance with some embodiments.

FIG. 7 illustrates an exemplary embodiment of a computer-readable medium, in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, well-known structures and devices are shown in block diagram form in order to facilitate describing the claimed subject matter.

It is to be understood that the following description of embodiments is not to be taken in a limiting sense. The scope of the present disclosure is not intended to be limited by the embodiments described hereinafter or by the drawings, which are taken to be illustrative only. The drawings are to be regarded as being schematic representations and elements illustrated in the drawings are not necessarily shown to scale. Rather, the various elements are represented such that their function and general purpose become apparent to a person skilled in the art.

All numerical values within the detailed description and the claims herein are modified by “about” or “approximately” the indicated value, and take into account experimental error and variations that would be expected by a person having ordinary skill in the art.

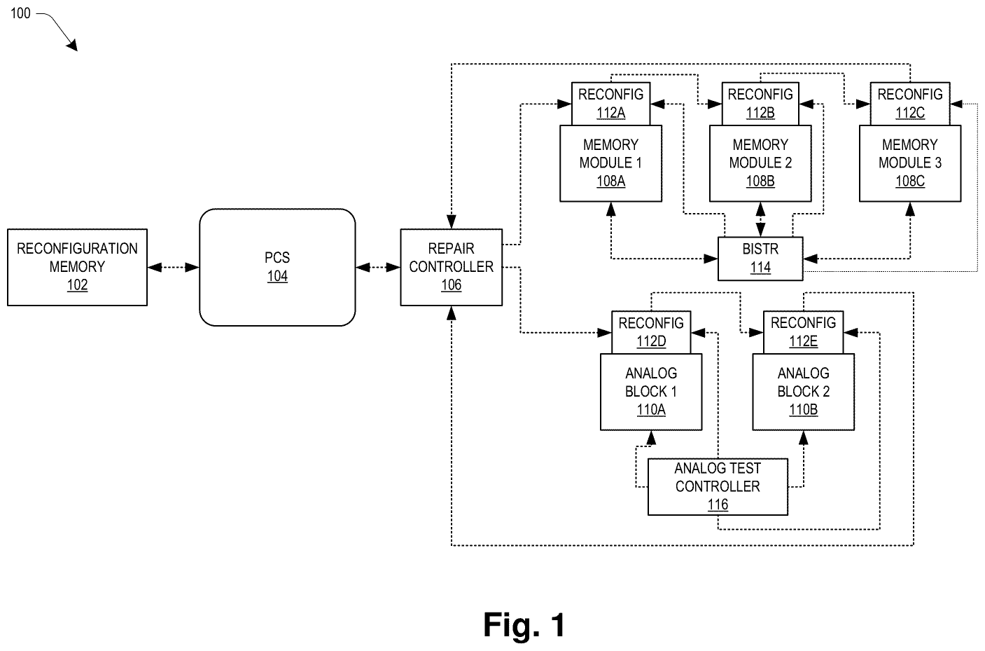

FIG. 1 is a block diagram of a device 100 comprising a reconfiguration memory 102 for storing reconfiguration data, a positional codec system (PCS) 104 for decoding the reconfiguration data, a repair controller 106 for programming memory modules 108A, 108B, 108C or analog blocks 110A, 110B with the reconfiguration data. The reconfiguration data may be stored in reconfiguration registers 112A, 112B, 112C, 112D, 112E associated with the memory modules 108A, 108B, 108C or analog blocks 110A, 110B during the start-up of the device 100. In some embodiments, a built-in self-test and repair (BISTR) module 114 tests the memory modules 108A, 108B, 108C to generate reconfiguration data and an analog test controller 116 tests the analog blocks 110A, 110B to generate reconfiguration data. Reconfiguration data for the memory modules 108A, 108B, 108C may include data for replacing defective memory regions, trim data (e.g., transistor speed or bias trim data), or other memory related reconfiguration data. Reconfiguration data for the analog blocks 110A, 110B may include trim data for analog circuits such as operational amplifiers, phase locked loops, analog to digital converters, or other analog circuits. In addition to trim data for analog circuits, reconfiguration data may include redundancy control data for replacing defective vias with redundant vias for die stacking, or other reconfiguration data.

In some embodiments, the reconfiguration memory 102 comprises a one-time-programmable (OTP) memory with non-volatile memory cells such as efuse-based cells or antifuse-based cells. The memory modules 108A, 108B, 108C may be volatile memories, such as static random access memories (SRAMs), or non-volatile memories, such as flash memories, with redundancy provisions for replacing cells. Redundant rows in the memory modules 108A, 108B, 108C can be used for repairing rows with faulty cells and redundant columns can be used for repairing columns with faulty cells. If a row or column includes one or more faulty cells, the defective row or column can be repaired by effectively replacing it with one of the redundant rows or columns by mapping the replacement in the associated reconfiguration register 112A, 112B, 112C.

If a region in a memory module 108A, 108B, 108C lacks a faulty cell, the associated reconfiguration register 112A, 112B, 112C is programmed with repair data set to null or zero such that no redundant element is used or additional trim parameter set. In some embodiments, on power-up of the device 100, all reconfiguration registers 112A, 112B, 112C, 112D, 112E are initialized to zero or null data. The repair controller 106 accesses the PCS 104 to read the reconfiguration data from the reconfiguration memory 102 and loads the reconfiguration data into the reconfiguration registers 112A, 112B, 112C, 112D, 112E.

In some embodiments, the BISTR 114 tests the memory modules 108A, 108B, 108C and repairs defective memory by programming the associated reconfiguration register 112A, 112B, 112C with reconfiguration data or tunes the memory modules 108A, 108B, 108C using trim parameters. Thus, during operation, the contents of the reconfiguration registers 112A, 112B, 112C may change compared to the reconfiguration data stored in the reconfiguration memory 102. In some embodiments, the BISTR 114 generates address sequences for accessing the memory modules 108A, 108B, 108C and storing test data sequences in the memory modules 108A, 108B, 108C according to a test program. The test data sequences may provide a set of data bits designed to identify various types of faults within the memory modules 108A, 108B, 108C. The BISTR 114 can scan the memory modules 108A, 108B, 108C by row, by column, or a combination of both.

The BISTR 114 analyzes error (or failure) data received from testing the memory modules 108A, 108B, 108C. The error (or failure) data may include the identities of faulty memory cells, which in turn can be used to determine an appropriate repair mechanism. Depending on the location and distribution of the failed memory cells, the repair could be done by row repair, column repair, or both. The BISTR 114 stores identities of faulty memory cells and, after determining the repair method, the BISTR 114 programs the associated reconfiguration register 112A, 112B, 112C with non-zero reconfiguration data.

The analog test controller 116 tests the analog blocks 110A, 110B and determines operational amplifier trim data by programming the associated reconfiguration register 112D, 112E with reconfiguration data during the tests. The analog test controller 116 analyzes performance or error data received from testing the analog blocks 110A, 110B and determines an appropriate repair or tuning mechanism. The analog test controller 116, after determining the repair or tuning method, programs the associated reconfiguration register 112D, 112E with non-zero reconfiguration data.

The device 100 may be subjected to multiple test/repair sessions by the BISTR 114 or the analog test controller 116. The device 100 typically requires multiple test/repair sessions that employ distinct testing algorithms. Each test/repair session may discover new faulty elements. After each test/repair session, the repair controller 106 transfers the contents of all the reconfiguration registers 112A, 112B, 112C, 112D, 112E to the PCS 104 for compression and storage access in the reconfiguration memory 102 to provide non-volatile storage of the reconfiguration data, regardless of whether the reconfiguration registers 112A, 112B, 112C, 112D, 112E store zero or non-zero reconfiguration data. In some embodiments, reconfiguration data is one byte in length or less. Since most of the elements in the memory modules 108A, 108B, 108C or the analog blocks 110A, 110B will not have a faulty elements, most of the n bytes of reconfiguration data will be zero (i.e., eight bits of logic zero).

In some embodiments, the reconfiguration memory 102 is portioned into dedicated segments to store reconfiguration data for respective test/repair sessions. The quantity of reconfiguration data to be written to a reconfiguration memory segment after each test/repair session is unknown before the test/repair session is started. Some devices 100 of a wafer lot may be more defective than other devices 100 in the wafer lot. Accordingly segments of the reconfiguration memory 102 are sized to accommodate anticipated worse case scenarios. In many instances this accommodation leads to unused storage in the segments of the reconfiguration memory 102. Additionally, the reconfiguration memory 102 may be costly in terms of device foot print and latency arising from reduced access speed for the reconfiguration memory 102 compared to other memory in the device 100.

In some embodiments, the PCS 104 employs data encoding to reduce the size of data written to reconfiguration memory 102 after each test/repair session, thereby facilitating the use of a smaller reconfiguration memory 102 and increasing access speed. The PCS 104 may employ positional encoding to store the position of the reconfiguration data in the stream of data read from the reconfiguration registers 112A, 112B, 112C, 112D, 112E to avoid storage of null or zero data. In some embodiments, the PCS 104 employs dictionary encoding to store reference entries for reconfiguration data to avoid storing multiple identical reconfiguration data entries. The dictionary is stored in the reconfiguration memory

In some embodiments, the PCS 104 employs a cache to reduce latency associated with the slower reconfiguration memory 102. The repair controller 106 can load the reconfiguration registers 112A, 112B, 112C, 112D, 112E using cached reconfiguration data rather than reconfiguration data from the reconfiguration memory 102 to reduce the time required to initialize the device 100.

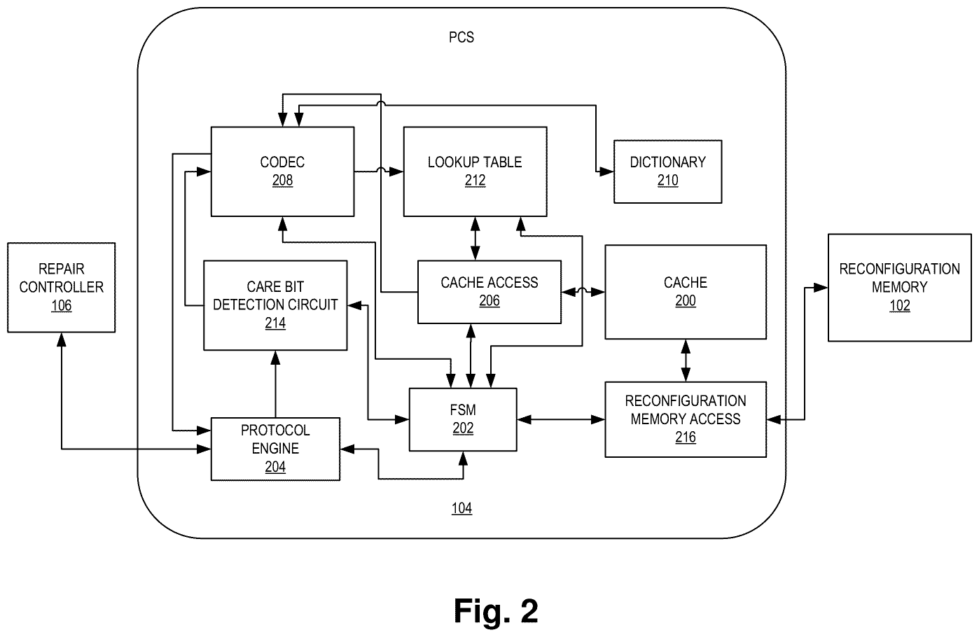

FIG. 2 is diagram of the PCS 104, in accordance with some embodiments. In the embodiment of FIG. 2, the PCS 104 comprises a cache 200. The PCS 104 is controlled by a finite state machine (FSM) 202. A protocol engine 204 interfaces between the repair controller 106 and the FSM 202. The protocol engine 204 receives the stream of test data from the repair controller 106. In some embodiments, the PCS 104 comprises a cache access module 206 for interfacing with the cache 200, a CODEC module 208 for encoding and decoding positional or library compression, a dictionary 210 for storing reference entries for recurring reconfiguration data, a lookup table (LUT) 212 for storing data in the cache 200, a care bit detection circuit 214 for identifying reconfiguration data in the stream of test data, and a reconfiguration memory access module 216 for reading from and writing to the reconfiguration memory 102.

In some embodiments, the FSM 202 controls the cache access module 206 to populate the cache 200 with previous reconfiguration data stored in the reconfiguration memory 102 to allow identification of existing reconfiguration data with reduced latency.

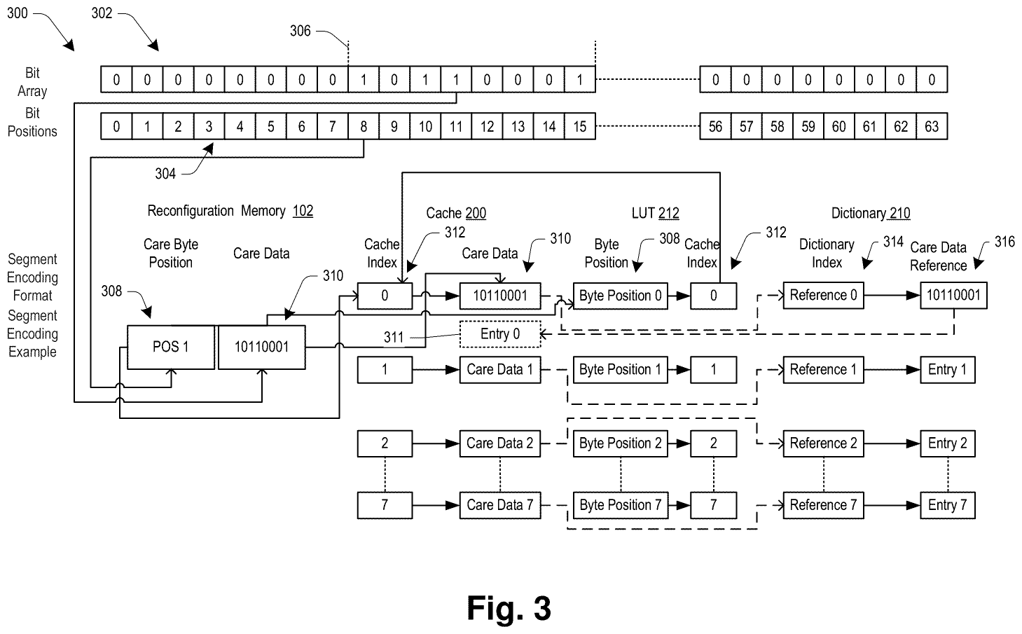

FIG. 3 is diagram 300 illustrating reconfiguration data processing with a cache 200, in accordance with some embodiments. Referring to FIG. 3, a stream 302 of test data is received by the repair controller 106 from the BISTR 114 or the analog test controller 116 shown in order by bit position 304. The stream 302 includes care data 306 representing reconfiguration data and zeros or null data for regions not requiring repair. For example, the care bit detection circuit 214 may identify care data at bit 8 in the stream 302 based on the non-zero value. Depending on the specific implementation the position of the care data may be referenced by byte (e.g., 8 bits) position or bit position. In the stream 302, the byte position corresponds to a particular element in the device 100, such as a memory cell. Reconfiguration data is stored in the reconfiguration memory 102 based on care byte position 308 and care data 310. For example the care data 306 is stored in the reconfiguration memory 102 in care byte position 1 with a care data value of “10110001”. The care data 310 is also stored in the cache 200 based on cache index 312 (e.g., index value 0). In some embodiments, the LUT 212 indicates the existence of null contents of the cache 200 based on care byte position 308 in response to a query on an arbitrary byte position sent by the repair controller 106. When the LUT 212 returns no cache index, the PCS 104 can return null or zero data to the repair controller 106. When the LUT 212 returns a valid cache index, the LUT 212 returns a valid cache index which is at cache index 312, and this index stored at LUT 212 can be used to generate a corresponding read response at the cache 200 and return valid care data 310 to the repair controller 106. To identify if previous care data exists for a given position, the LUT 212 is accessed. If an entry exists, the cache 200 is accessed to retrieve the previous care data.

In some embodiments, dictionary encoding is used to reduce data size. The dictionary 210 stores a dictionary index 314 and care reference data values 316 for recurring care data values. Prior to writing care data to the reconfiguration memory 102, recurring care data values are identified and stored in the dictionary 210. Cache entries are updated to replace the care data value in the care data 310 with the dictionary index value 316 as shown in the dashed box 311. When the data in the cache 200 is transferred to the reconfiguration memory 102, the value of the dictionary index 314 is stored in place of the care data value, which can be much smaller than the care data, thereby reducing memory space required for the entry. The dictionary 210 is stored in the reconfiguration memory 102. The dictionary 210 may be updated in the reconfiguration memory 102 over time as additional recurring entries are identified. The newly-added dictionary entries may be used going forward to compress future care data values, since previous entries cannot be overwritten due to the OTP nature of the reconfiguration memory 102.

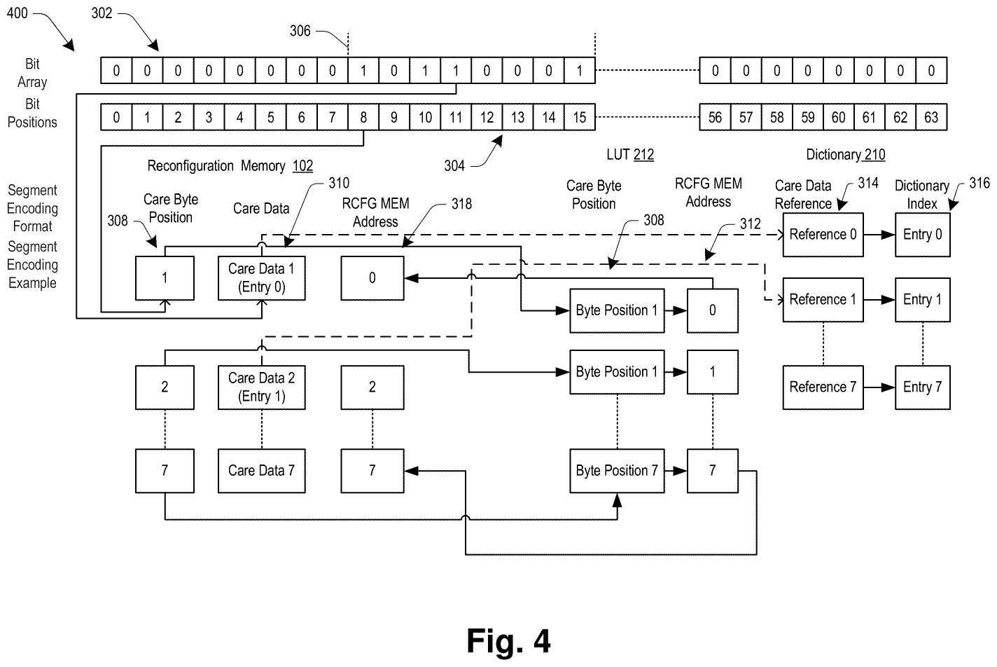

FIG. 4 is diagram 400 illustrating reconfiguration data processing without the cache 200, in accordance with some embodiments. Referring to FIG. 4, reconfiguration data is stored in the reconfiguration memory 102 based on the care byte position 308 and the care data 310. For example the care data 306 is stored in the reconfiguration memory 102 in byte position 1 with a care data value of “10110001”. Since the cache 200 is not present, a reconfiguration memory (RCFG MEM) address 318 is used to identify the care byte data storage location. The care byte position 308 and RCFG MEM address 318 are stored in the LUT 212. Similar to FIG. 3, in embodiments using dictionary encoding, reference data entries 314 are stored for recurring care byte data values based on dictionary index 316 and the dictionary index 316 is stored in the reconfiguration memory 102 in place of the care data.

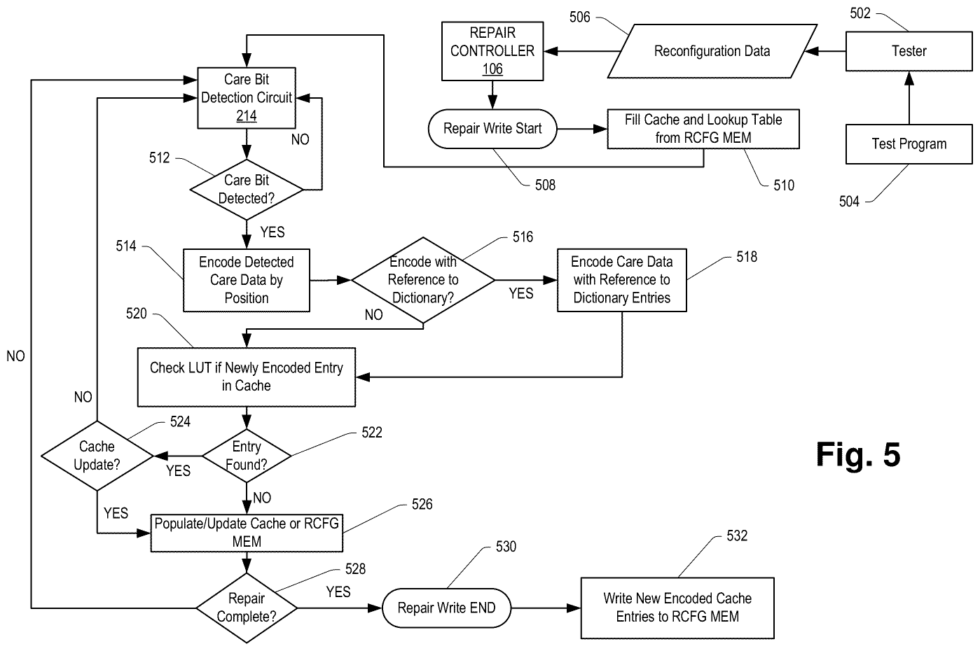

FIG. 5 is a diagram of a method 500 for writing reconfiguration data in a device, in accordance with some embodiments. For purposes of illustration, the method 500 is described for the embodiment of the PCS 104 in FIG. 2 with a cache 200. A tester 502 (e.g., the BISTR 114 or the analog test controller 116) executes a test program 504 to generate a reconfiguration data stream 506 comprising care data and zero or null data. The repair controller 106 starts a repair write operation at 508. The PCS 104 populates the cache 200 and the LUT 212 at 510 reading previous reconfiguration data from the reconfiguration memory 102.

The care bit detection circuit 214 checks for care bits in the reconfiguration data stream 506. If a care bit is detected at 512, the CODEC 208 encodes the detected care data by position at 514. At 516, the need for dictionary encoding is determined. For example, a threshold may be used such that if the same care data is seen at least N times, a dictionary entry is created. If dictionary encoding is chosen at 516, the dictionary 210 is updated to create a dictionary reference for the care data at 518. After generating the dictionary entry at 518 or if dictionary encoding is not chosen at 516, the LUT 212 is accessed at 520 to determine if an entry for the care data and the associated position are already stored in the cache 200. If a cache entry is found at 522, the need for a cache update is identified at 524. If the care data has not changed, the cache 200 does not need to be updated at 524 and the method 500 returns to 214 to detect the next care data. If the care data has changed at 524 or no cache entry is identified at 522, the cache 200 or the reconfiguration memory 102 may be updated at 526. If the care data has changed for the care byte position, a logical “OR” of the previous care data value and the new care data value may be used to update the reconfiguration memory 102, since it is OTP in some embodiments. There are cases where such an overwriting scenario will cause the device 100 to fail and the device 100 will be rejected during test.

If the cache 200 does not need to be updated at 524 and the method 500 returns to 214 to detect the next care data. If the repair process is not complete at 528, the method 500 returns to 214 to detect the next care data. If the repair process is complete at 528, the repair write operation ends at 530 and the reconfiguration memory 102 is updated with new reconfiguration data entries at 532. Writing only new entries to the reconfiguration memory 102 conserves space in the reconfiguration memory 102 and reduces latency.

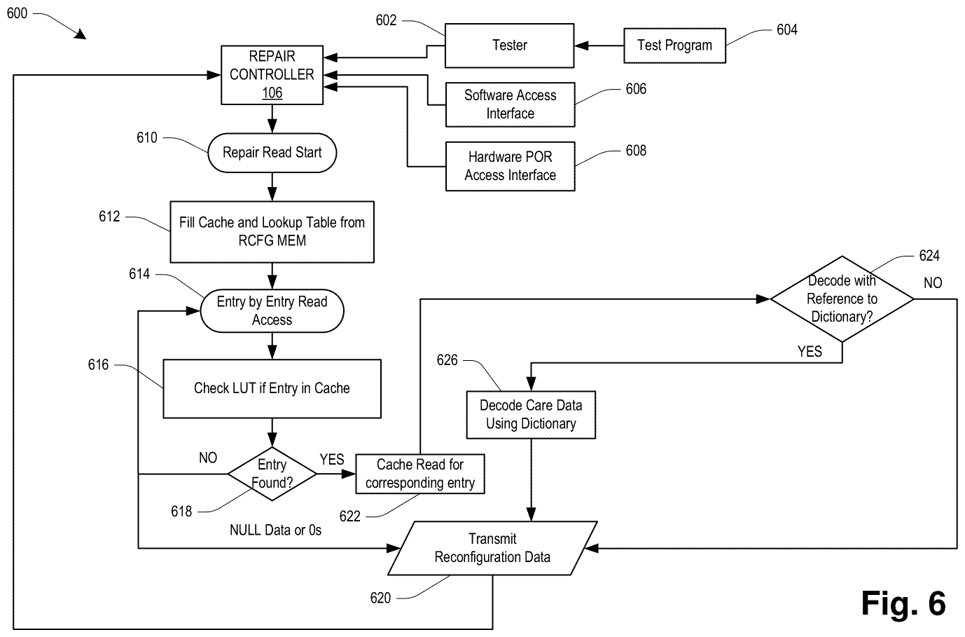

FIG. 6 is a diagram of a method 600 for reading reconfiguration data in a device 100, in accordance with some embodiments. A read request may originate from a tester 602 (e.g., the BISTR 114 or the analog test controller 116) executing a test program 604 or during initialization of the device 100 through a software access interface 608 or a hardware power-on-reset (POR) access interface 608. The repair read operation is initiated at 610. The PCS 104 populates the cache 200 and the LUT 212 at 612 by reading previous reconfiguration data from the reconfiguration memory 102.

The repair controller 106 processes the repair data read entry by entry at 614. The LUT 212 is accessed at 616 to determine if a repair entry is already stored in the cache 200 based on the associated position. If a cache entry is not found at 618, null data or zeros are transmitted to the repair controller 106 as the reconfiguration data at 620 and the method 600 returns to 614 for the next read entry. If a cache entry is found at 618, a cache read is performed at 622 for the corresponding care data entry. At 624, the need for dictionary decoding is determined. If dictionary decoding is chosen at 624, the dictionary 210 is used decode the care data 626 and transmits the reconfiguration data at 620. If no corresponding dictionary entry is present, the care data 310 is transmitted as the reconfiguration data at 620. After transmitting reconfiguration data (or null data) at 620, the method 600 returns to 614 for the next entry.

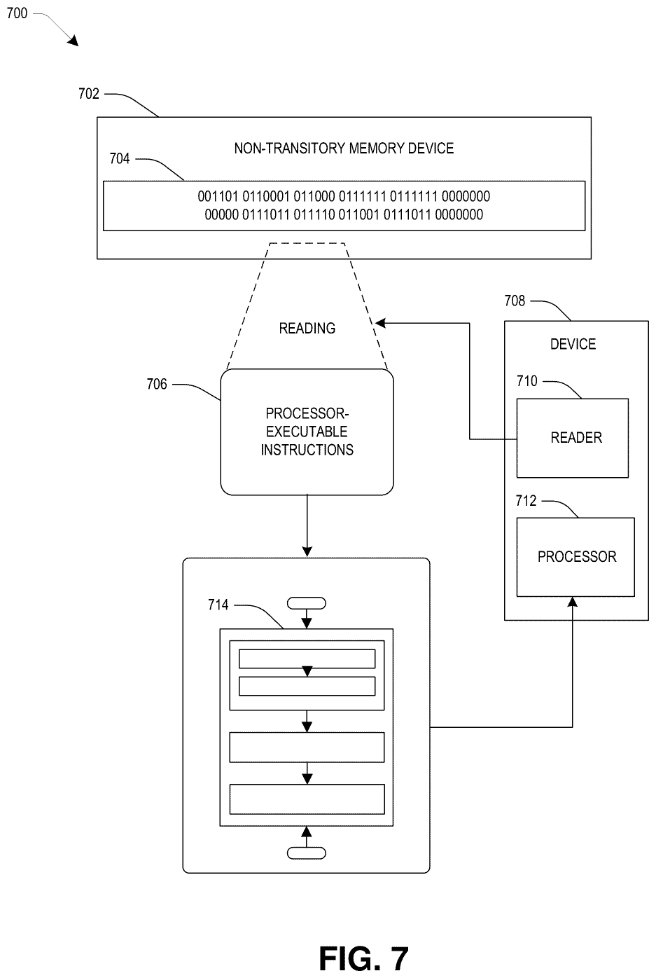

FIG. 7 illustrates an exemplary embodiment 700 of a computer-readable medium 702, in accordance with some embodiments. One or more embodiments involve a computer-readable medium comprising processor-executable instructions configured to implement one or more of the techniques presented herein, such as the methods 500, 600. The embodiment 700 comprises a non-transitory computer-readable medium 702 (e.g., a CD-R, DVD-R, flash drive, a platter of a hard disk drive, etc.), on which is encoded computer-readable data 704. This computer-readable data 704 in turn comprises a set of processor-executable computer instructions 706 that, when executed by a computing device 708 including a reader 710 for reading the processor-executable computer instructions 706 and a processor 712 for executing the processor-executable computer instructions 706, are configured to facilitate operations according to one or more of the principles set forth herein. In some embodiments, the processor-executable computer instructions 706, when executed, are configured to facilitate performance of a method 714, such as at least some of the aforementioned method(s). In some embodiments, the processor-executable computer instructions 706, when executed, are configured to facilitate implementation of a system, such as at least some of the one or more aforementioned system(s). Many such computer-readable media may be devised by those of ordinary skill in the art that are configured to operate in accordance with the techniques presented herein.

The term “computer readable media” and/or the like may include communication media. Communication media typically embodies computer readable instructions or other data in a “modulated data signal” such as a carrier wafer or other transport mechanism and includes any information delivery media. The term “modulated data signal” may include a signal that has one or more of its characteristics set or changed in such a manner as to encode information in the signal.

In an embodiment of the techniques presented herein, a method comprises receiving a stream of test data associated with a device, identifying first care data at a first position in the stream of test data corresponding to a first element of the device, and sending a first write command comprising the first care data and the first position to a reconfiguration memory.

In an embodiment of the techniques presented herein, the method comprises identifying second care data at a second position in the stream of test data corresponding to a second element of the device and, responsive to previous reconfiguration data not comprising an entry associated with the second position, sending a second write command comprising the second care data and the second position to the reconfiguration memory.

In an embodiment of the techniques presented herein, the method comprises responsive to the previous reconfiguration data comprising an entry associated with the second position, sending a third write command to overwrite the second care data in an entry in the reconfiguration memory associated with the second position.

In an embodiment of the techniques presented herein, the method comprises performing a logical OR on the second care data and previous care data in an entry in the reconfiguration memory associated with the second position, and sending a third write command to overwrite the entry in the reconfiguration memory associated with the second position based on the logical OR.

In an embodiment of the techniques presented herein, the method comprises loading previous care data entries of the previous reconfiguration data in a cache according to a cache index, loading positions associated with the previous care data entries of the previous reconfiguration data in a lookup table, and linking the cache and the lookup table by the cache index.

In an embodiment of the techniques presented herein, the method comprises loading previous care data entries of the previous reconfiguration data in a lookup table, and loading positions associated with the previous care data entries of the previous reconfiguration data in the lookup table.

In an embodiment of the techniques presented herein, the method comprises storing the first care data in a dictionary, wherein sending the first write command comprises sending the first position and a reference to an entry in the dictionary for the first care data to the reconfiguration memory.

In an embodiment of the techniques presented herein, the method comprises sending a command to store the dictionary to the reconfiguration memory.

In an embodiment of the techniques presented herein, the method comprises receiving a read request associated with a second position corresponding to a second element of the device, responsive to a first entry being present in the reconfiguration memory corresponding to the second position, sending second care data associated with the first entry for the read request, and responsive to the first entry not being present in the reconfiguration memory corresponding to the second position, sending null data for the read request.

In an embodiment of the techniques presented herein, the method comprises loading a memory with previous reconfiguration data associated with the device from the reconfiguration data, accessing the memory to determine whether a second entry corresponding to the first entry is present in the memory, and responsive to the second entry being present in the memory, retrieving the second care data from the second entry.

In an embodiment of the techniques presented herein, a positional codec system comprises a protocol engine configured to receive a stream of test data associated with a device, a detection circuit configured to identify first care data at a first position in the stream of test data corresponding to a first element of the device, and a first access module configured to send a first write command to store the first care data and the first position to a reconfiguration memory.

In an embodiment of the techniques presented herein, the positional codec system comprises a memory storing previous reconfiguration data associated with the device loaded from the reconfiguration memory, wherein the detection circuit is configured to identify second care data at a second position in the stream of test data corresponding to a second element of the device and a second access module configured to identify an entry in the memory corresponding to the second position, wherein the first access module is configured to send a second write command to store the second care data and the second position to the reconfiguration memory responsive to the second access module not identifying the entry in the memory corresponding to the second position.

In an embodiment of the techniques presented herein, the previous reconfiguration data comprises previous care data entries and positions associated with the previous care data entries, and the memory comprises a cache storing the previous care data entries according to a cache index and a lookup table storing the positions associated with the previous care data entries linked by the cache index.

In an embodiment of the techniques presented herein, the previous reconfiguration data comprises previous care data entries and positions associated with the previous care data entries, and the memory comprises a lookup table storing the previous care data entries and the positions associated with the previous care data entries.

In an embodiment of the techniques presented herein, the positional codec system comprises a dictionary storing the first care data based on a dictionary index, wherein the first access module is configured to send the first write command comprising the dictionary index to the reconfiguration memory.

In an embodiment of the techniques presented herein, the positional codec system comprises a memory storing previous reconfiguration data associated with the device loaded from the reconfiguration memory, wherein the protocol engine is configured to receive a read request associated with a second position corresponding to a second element of the device and a second access module configured to responsive to a first entry being present in the memory corresponding to the second position, send second care data associated with the first entry for the read request, and responsive to the first entry not being present in the memory corresponding to the second position, sending null data for the read request.

In an embodiment of the techniques presented herein, a device comprises a reconfiguration memory, a module comprising elements and a reconfiguration register, a repair controller configured to receive a stream of test data associated with the module, and a positional codec system comprising a protocol engine configured to receive the stream of test data from the repair controller, a detection circuit configured to identify first care data at a first position in the stream of test data corresponding to a first element of the elements in the module, and a first access module configured to store the first care data and the first position in the reconfiguration memory, wherein the repair controller is configured to program the reconfiguration register using the first care data to set a parameter associated with the first element or designate a second element as a replacement for the first element.

In an embodiment of the techniques presented herein, the positional codec system comprises a memory storing previous reconfiguration data associated with the device loaded from the reconfiguration memory, wherein the detection circuit is configured to identify second care data at a second position in the stream of test data corresponding to a third element of the elements in the module and a second access module configured to identify an entry in the memory corresponding to the second position, wherein the first access module is configured to store the second care data and the second position in the reconfiguration memory responsive to the second access module not identifying the entry in the memory corresponding to the second position.

In an embodiment of the techniques presented herein, the previous reconfiguration data comprises previous care data entries, and positions associated with the previous care data entries, and the memory comprises a cache storing the previous care data entries according to a cache index, and a lookup table storing the positions associated with the previous care data entries linked by the cache index.

In an embodiment of the techniques presented herein, the positional codec system comprises a dictionary storing the first care data based on a dictionary index, and the first access module is configured to store the dictionary index in an entry of the reconfiguration memory.

Any aspect or design described herein as an “example” and/or the like is not necessarily to be construed as advantageous over other aspects or designs. Rather, use of the word “example” is intended to present one possible aspect and/or implementation that may pertain to the techniques presented herein. Such examples are not necessary for such techniques or intended to be limiting. Various embodiments of such techniques may include such an example, alone or in combination with other features, and/or may vary and/or omit the illustrated example.

Various operations of embodiments are provided herein. In an embodiment, one or more of the operations described may constitute computer readable instructions stored on one or more computer readable media, which if executed by a computing device, will cause the computing device to perform the operations described. The order in which some or all of the operations are described should not be construed as to imply that these operations are necessarily order dependent. Alternative ordering may be implemented without departing from the scope of the disclosure. Further, it will be understood that not all operations are necessarily present in each embodiment provided herein. Also, it will be understood that not all operations are necessary in some embodiments.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing at least some of the claims.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims may generally be construed to mean “one or more” unless specified otherwise or clear from context to be directed to a singular form. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated example implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A method comprising:
receiving a stream of test data associated with a device;
identifying first care data at a first position in the stream of test data corresponding to a first element of the device; and
sending a first write command comprising the first care data and the first position to a reconfiguration memory.

2. The method of claim 1, comprising:
identifying second care data at a second position in the stream of test data corresponding to a second element of the device; and
responsive to previous reconfiguration data not comprising an entry associated with the second position, sending a second write command comprising the second care data and the second position to the reconfiguration memory.

3. The method of claim 2, comprising:
responsive to the previous reconfiguration data comprising an entry associated with the second position, sending a third write command to overwrite the second care data in an entry in the reconfiguration memory associated with the second position.

4. The method of claim 2, comprising:
performing a logical OR on the second care data and previous care data in an entry in the reconfiguration memory associated with the second position; and
sending a third write command to overwrite the entry in the reconfiguration memory associated with the second position based on the logical OR.

5. The method of claim 2, comprising:
loading previous care data entries of the previous reconfiguration data in a cache according to a cache index;
loading positions associated with the previous care data entries of the previous reconfiguration data in a lookup table; and
linking the cache and the lookup table by the cache index.

6. The method of claim 2, comprising:
loading previous care data entries of the previous reconfiguration data in a lookup table; and
loading positions associated with the previous care data entries of the previous reconfiguration data in the lookup table.

7. The method of claim 1, comprising:
storing the first care data in a dictionary, wherein:
sending the first write command comprises:
sending the first position and a reference to an entry in the dictionary for the first care data to the reconfiguration memory.

8. The method of claim 7, comprising:
sending a command to store the dictionary to the reconfiguration memory.

9. The method of claim 1, comprising:
receiving a read request associated with a second position corresponding to a second element of the device;
responsive to a first entry being present in the reconfiguration memory corresponding to the second position, sending second care data associated with the first entry for the read request; and
responsive to the first entry not being present in the reconfiguration memory corresponding to the second position, sending null data for the read request.

10. The method of claim 9, comprising:
loading a memory with previous reconfiguration data associated with the device from the reconfiguration data;
accessing the memory to determine whether a second entry corresponding to the first entry is present in the memory; and
responsive to the second entry being present in the memory, retrieving the second care data from the second entry.

11. A positional codec system, comprising:
a protocol engine configured to receive a stream of test data associated with a device;
a detection circuit configured to identify first care data at a first position in the stream of test data corresponding to a first element of the device; and
a first access module configured to send a first write command to store the first care data and the first position to a reconfiguration memory.

12. The positional codec system of claim 11, comprising:
a memory storing previous reconfiguration data associated with the device loaded from the reconfiguration memory, wherein:
the detection circuit is configured to identify second care data at a second position in the stream of test data corresponding to a second element of the device; and
a second access module configured to identify an entry in the memory corresponding to the second position, wherein:
the first access module is configured to send a second write command to store the second care data and the second position to the reconfiguration memory responsive to the second access module not identifying the entry in the memory corresponding to the second position.

13. The positional codec system of claim 12, wherein:
the previous reconfiguration data comprises:
previous care data entries; and
positions associated with the previous care data entries; and
the memory comprises:
a cache storing the previous care data entries according to a cache index; and
a lookup table storing the positions associated with the previous care data entries linked by the cache index.

14. The positional codec system of claim 12, wherein:
the previous reconfiguration data comprises:
previous care data entries; and
positions associated with the previous care data entries; and
the memory comprises:
a lookup table storing the previous care data entries and the positions associated with the previous care data entries.

15. The positional codec system of claim 11, comprising:
a dictionary storing the first care data based on a dictionary index, wherein:
the first access module is configured to send the first write command comprising the dictionary index to the reconfiguration memory.

16. The positional codec system of claim 11, comprising:
a memory storing previous reconfiguration data associated with the device loaded from the reconfiguration memory, wherein:
the protocol engine is configured to receive a read request associated with a second position corresponding to a second element of the device; and
a second access module configured to:
responsive to a first entry being present in the memory corresponding to the second position, send second care data associated with the first entry for the read request; and
responsive to the first entry not being present in the memory corresponding to the second position, sending null data for the read request.

17. A device, comprising:
a reconfiguration memory;
a module comprising:
elements; and
a reconfiguration register;
a repair controller configured to receive a stream of test data associated with the module; and
a positional codec system, comprising:
a protocol engine configured to receive the stream of test data from the repair controller;
a detection circuit configured to identify first care data at a first position in the stream of test data corresponding to a first element of the elements in the module; and
a first access module configured to store the first care data and the first position in the reconfiguration memory, wherein:
the repair controller is configured to program the reconfiguration register using the first care data to set a parameter associated with the first element or designate a second element as a replacement for the first element.

18. The device of claim 17, wherein:
the positional codec system comprises:
a memory storing previous reconfiguration data associated with the device loaded from the reconfiguration memory, wherein:
the detection circuit is configured to identify second care data at a second position in the stream of test data corresponding to a third element of the elements in the module;
and
a second access module configured to identify an entry in the memory corresponding to the second position, wherein:
the first access module is configured to store the second care data and the second position in the reconfiguration memory responsive to the second access module not identifying the entry in the memory corresponding to the second position.

19. The device of claim 18, wherein:
the previous reconfiguration data comprises:
previous care data entries; and
positions associated with the previous care data entries; and
the memory comprises:
a cache storing the previous care data entries according to a cache index; and
a lookup table storing the positions associated with the previous care data entries linked by the cache index.

20. The device of claim 17, wherein:
the positional codec system comprises:
a dictionary storing the first care data based on a dictionary index, and
the first access module is configured to store the dictionary index in an entry of the reconfiguration memory.
